(19) United States
(12) Patent Application Publication
(10) Pub. No.: US 2011/0315211 A1
(43) Pub. Date: Dec. 29, 2011

(54) SOLAR CELL FRONT ELECTRODE WITH AN ANTIREFLECTION COATING

(75) Inventors: Bernard Nghiem, Arsy (FR); Eddy Royer, Villemomble (FR); Emmanuelle Peter, Aix (FR); Georges Zagdoun, La Garenne Colombes (FR)

(73) Assignee: Saint-Gobain Glass France, Courbevoie (FR)

(21) Appl. No.: 13/120,312

(22) PCT Filed: Sep. 24, 2009
(86) PCT No.: PCT/FR2009/051810

§ 371 Date: Jun. 22, 2011

(30) Foreign Application Priority Data
Sep. 24, 2008 (FR) 0856418

(51) Int. Cl. H01L 31/0224; H01L 31/18; H01L 31/0216

(52) U.S. Cl. 136/256; 438/57; 438/72; 257/E31.119; 257/E31.124

(57) ABSTRACT

A carrier substrate, includes a substrate especially having a glass function, transparent at least in the visible and near-infrared ranges and receiving a conducting electrode which is transparent at least in the visible and near-infrared ranges, this electrode carrier substrate being intended to constitute, in combination with functional elements, a solar cell. This carrier substrate is such that: the electrode includes a micromesh made of conducting material having submillimeter-sized openings; and this micromesh is in contact with an at least slightly conducting antireflection coating facing that one of the functional elements with which it is intended to be in contact. An aspect of the present invention also relates to the use of such a carrier substrate as constituent element of a solar cell and to a process for fabricating the substrate.

The present invention relates to a carrier substrate intended to be used particularly in the construction of a solar cell and more particularly at the front electrode of a solar cell.

Within the context of the invention, the front electrode of a solar cell is that one of the two electrodes through which the light rays pass first.

It is known that in certain solar cells the electrodes are formed from transparent conductive oxides (called TCO) such as especially fluorine-doped tin oxide SnO₂:F, aluminum-doped zinc oxide ZnO:Al (called AZO) and ITO (a mixed indium tin oxide). These oxides have the drawback of absorbing in the blue of the visible spectrum and in a large part of the infrared spectrum, so that, on the one hand, part of the solar spectrum cannot be converted into electrical energy and, on the other hand, this excludes the use of certain photovoltaic materials that are sensitive in these wavelength ranges.

Moreover, it is known that SnO₂:F, although being very stable to ambient moisture, has the drawback of being reduced to the metallic tin form when it is subjected to a hydrogen plasma during the operation of depositing functional layers, such as silicon or germanium layers, while ITO layers have the same drawback. On the other hand, ZnO:Al, which is very stable in a hydrogen plasma, becomes rapidly corroded after the texturing step, due to the effect of ambient moisture, causing serious problems while the glass product is being stored. In addition in the case of AZO, it is known that, to be conducting, its layers must be in the crystalline state, this having the drawback of requiring either an operation to anneal the layers deposited by room-temperature magnetron sputtering, said operation constituting an additional step increasing the cost of the operation, or a high-temperature deposition, which makes the deposition process more complex and more expensive.

Finally, the TCOs forming the electrodes have refractive indices (n<1.9) that are far from the refractive index of silicon (n=3.8) with which they are in contact. This means, in order to reduce the reflection occurring at the interface between these two elements, the surface of the TCOs, such as AZO or ITO, has to undergo a nanotexturing step, which represents an additional operation again increasing the cost of the product.

To summarize, the transparent conductive oxides used for forming the electrodes of glass systems, such as for solar cells, each have, to various degrees, specific drawbacks.

The objective of the present invention is to provide a solar cell carrier substrate making it possible to avoid the aforementioned drawbacks, the electrode of which is capable of fulfilling its electrical conduction function both throughout the visible spectrum and in the near-infrared, which, in addition, is insensitive to a hydrogen plasma and to ambient moisture, and the constitution of which is such that it allows the conduction function provided by the electrode to be decoupled from the other functions thereof, thus giving the designer greater freedom in the choice of materials used.

Thus, one subject of the present invention is a carrier substrate, comprising a substrate especially having a glass function, transparent at least in the visible and near-infrared ranges and receiving a conducting electrode which is transparent at least in the visible and near-infrared ranges, this electrode carrier substrate being intended to constitute, in combination with functional elements, a solar cell, this carrier substrate being such that:
the electrode comprises a, and preferably consists of one, micromesh made of conducting material having submillimeter-sized openings; and
this micromesh is in contact with an at least slightly conducting antireflection coating facing that one of the functional elements with which it is intended to be in contact.

Beside the fact that the present invention makes it possible to remedy the various drawbacks mentioned above, it should be noted that, because of the high conductivity of its electrode compared with that of electrodes employing metal oxides, the antireflection layer that it supports can have only a low conductivity. Indeed, the present invention makes it possible to decouple, in other words, separate, the electrical conduction function provided by the front electrode from the other functions that are assigned thereto. The solar cell designer will thus have a greater freedom of choice of materials and their arrangement in the construction of said cells.

The present invention thus allows the designer to employ absorbers of types other than those normally used in conjunction with electrodes employing metal oxides, thus making it possible in particular to extend the range of photovoltaic conversion into the near-infrared.

The invention makes it possible to achieve a good compromise between transmission of radiation through the carrier substrate, at least in the visible and near-infrared ranges, and conductivity of the carrier substrate electrode. This improves the photovoltaic efficiency of a solar cell in which the carrier substrate according to the invention is integrated as front face, thanks both to good transmission of radiation into the absorbing elements of the solar cell, within the useful wavelength ranges for these elements, and to optimum charge collection from the absorbing elements resulting from the conductivity both of the antireflection coating and of the electrode.

Advantageously, the micromesh may be based on a metal or a metal alloy, especially silver or gold.

According to one embodiment, the micromesh comprises a thin-film multilayer stack comprising at least a metallic first layer and two dielectric-based coatings located one below and the other above the metallic first layer, and a protective metallic layer placed immediately above and in contact with the metallic first layer.

The openings of the micromesh preferably have an aperiodic distribution in at least one direction. The distribution of said submillimeter-sized openings will also be preferably random.

Moreover, the antireflection coating may consist of a multilayer stack comprising at least two thin layers made of a dielectric material, the refractive indices of the layers of which, in contact with the glass substrate and intended to be in contact with the functional element respectively, have refractive indices close to the refractive indices of said substrate and said element. The multilayer stack of the antireflection coating may also consist of at least three thin layers, the refractive indices of which are alternately high and low.

Preferably, that layer of the antireflection multilayer stack in contact with the substrate will be based on mixed oxides, nitrides or oxynitrides based on silicon (Si), tin (Sn) or zinc (Zn), used alone or as a mixture, and optionally doped (with fluorine, aluminum or antimony), and the layer in contact with the functional multilayer stack will be based on at least one transparent conductive oxide chosen especially from titanium oxide (TiO₂), zinc oxide (ZnO), tin oxide (SnO₂), mixed tin zinc oxide (SnZnO), indium tin oxide (ITO), mixed indium zinc oxide (IZO) and mixed indium zinc gallium oxide (IZGO) and optionally doped with Nb, Ta, Al, Sb or F.

Advantageously, the first layers in contact with the substrate function as barriers for stopping alkaline metals from said substrate.

In one particularly advantageous embodiment of the invention, the substrate may include, on its external face, an antireflection layer.

According to the invention, the resistivity of the layers of the antireflection coating is equal to or less than 500 milliohms.cm, preferably equal to or less than 50 milliohms.cm and especially between 0.1 and 50 milliohms.cm (limits inclusive), preferably between 5 and 50 milliohms.cm (limits inclusive).

In addition, the metal micromesh may be covered with an overblocker element.

In one embodiment, the layer of the antireflection element, which is intended to be at the interface between the functional element and the antireflection element, is lightly doped or even undoped so as to match its work function to the material of the functional element.

Advantageously, this layer consists of a highly doped transparent conductive oxide (TCO) preferably with a thickness of between 5 and 10 nanometers.

Another subject of the present invention is a solar cell incorporating a carrier substrate as described above and yet another subject is the use of a carrier substrate as described above for constituting a solar cell.

The final subject of the present invention is a process for fabricating a carrier substrate as described above, characterized in that it comprises the steps consisting in:
depositing a mask layer on the substrate using a solution of stabilized colloidal particles dispersed in a solvent;
drying the mask layer until a two-dimensional network of interstices is obtained;
depositing a conducting, especially metallic, micromesh material in these interstices until at least a fraction of the depth of the interstices has been filled; and
depositing the at least slightly conducting antireflection coating facing that one of the functional elements with which it is intended to be in contact.

Preferably, the substrate on which the mask layer is deposited is provided on its external face with an antireflection coating.

One embodiment of the present invention is described below by way of non-limiting example with reference to the appended drawing in which:

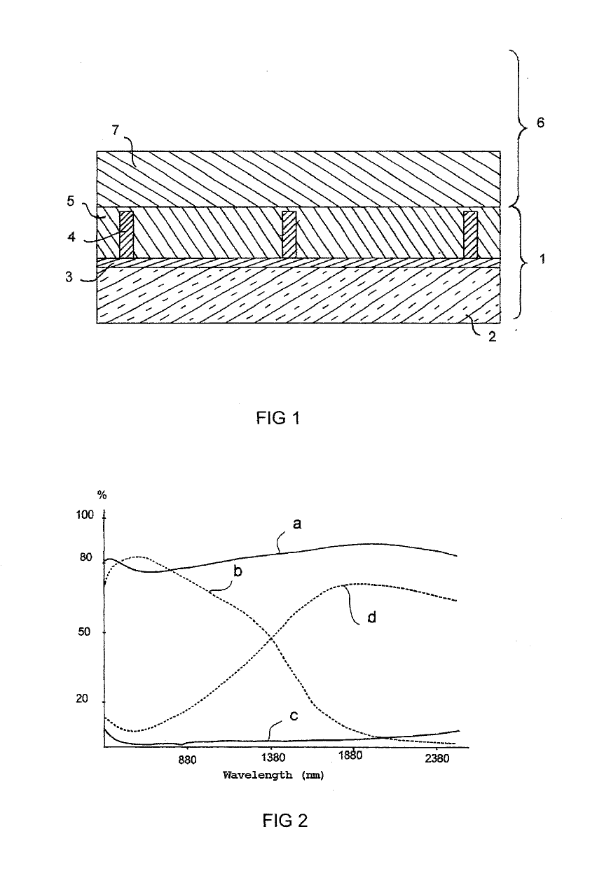

FIG. 1 is a schematic view in vertical cross section of a first exemplary embodiment of a solar cell employing a carrier substrate according to the present invention;

FIG. 2 shows representative curves of the optical transmission and absorption spectra of a carrier substrate respectively according to the invention and according to the prior art, namely in which the front electrode employ is a TCO;

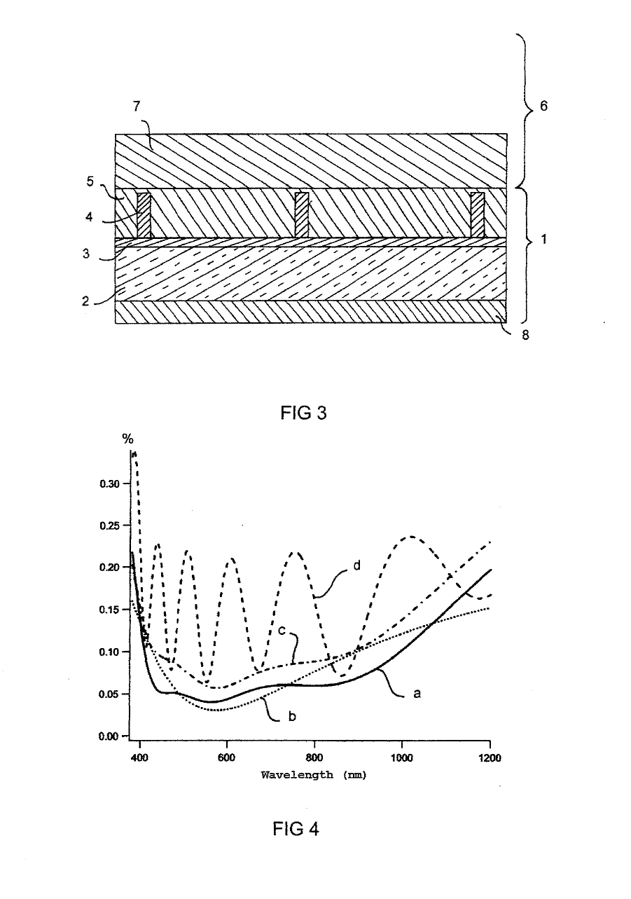

FIG. 3 is a schematic view in vertical cross section of an alternative embodiment of the solar cell shown in FIG. 1; and

FIG. 4 shows representative curves of the optical reflection spectra of a carrier substrate according to the prior art (curve d) and of a carrier substrate according to the invention, the antireflection coating of which is of the monolayer type (curve b), bilayer type (curve c) and trilayer type with an external antireflection layer (curve a), respectively.

FIG. 1 shows an exemplary embodiment of a carrier substrate 1 according to the invention applied to the production of a solar cell.

This carrier substrate 1 thus comprises a substrate 2, preferably made of an extra-clear glass, having a very low content of iron oxide(s), for example of the type sold under the brand name “DIAMANT” by Saint-Gobain Vitrage, deposited on the internal face of which, facing the silver, is a layer 3 of a tie element, especially one made of Si₃N₄.

Next, deposited on this assembly is an electrode which is capable, as is known, of having both conductivity and transparency qualities. According to the invention, this electrode consists of a conducting, especially metallic, micromesh 4 having submillimeter-sized openings in an aperiodic arrangement in at least one direction. The strands of the micromesh 4 are of submillimeter size, preferably of the order of a few hundred nanometers to a few tens of microns. The micromesh 4 is arranged, or distributed, on the substrate 2 in such a way that it is transparent, at least in the visible and near-infrared range.

Preferably, this micromesh 4 is obtained according to the teaching of patent application WO-A-2008/132397 (PCT/FR2008/050505). More precisely, in a first step, a mask is firstly formed on the layer 3 covering the substrate 2, by depositing on said layer one or more layers obtained from a solution of stabilized colloidal particles dispersed in a solvent, and then by drying this mask. The drying causes the layer of the latter to contract and results in friction of the nanoparticles on the surface, resulting in a tensile stress in the layer which, by relaxing, forms interstices that constitute a two-dimensional network with substantially straight edges and the mesh cells of which are random and aperiodic in at least one direction.

In the second step, an electrically conducting micromesh material, especially one based on a metal such as silver, is deposited into the interstices of the mask, typically by physical vapor deposition and especially by sputtering or by evaporation, until at least a fraction of the depth of the interstices has been filled, and then the mask layer is removed, until revealing the micromesh based on the conducting micromesh material used.

In the present embodiment of the invention, it is preferred to use silver, but of course it could be possible to use (at least) a layer of any other metal or layer of metal alloys possessing good conductivity properties, especially one such as gold.

As a variant, the micromesh 4 comprises a thin-film multilayer stack comprising at least a metallic first layer and two coatings based on oxides, on transparent conductive oxides and on dielectrics, one coating being located below and the other above the metallic first layer, and also a metallic protective layer placed immediately above and in contact with the metallic first layer. Embodiments of this multilayer stack structure may be found in the following patent applications: EP 718 250, EP 847 965, EP 1 366 001, EP 1 412 300, EP 1 151 480 or EP 722 913, or else temperable multilayer stacks comprising at least three silver layers, as described in patent application EP 1 689 690. Given below as examples are the thicknesses of the constituent layers of said pattern for a multilayer stack consisting of three layers which are, preferably:

### ZnO/Ag/ . . . ZnO/Si₃N₄ (7 to 15/10 to 17/ . . . 7 to 15/25 to 65 nm)

and preferably: ZnO/Ag/Ti/ZnO/Si₃N₄
7 to 15/10 to 17/0.2 to 2/7 to 15/25 to 65 nm.

Likewise, the thicknesses of the constituent layers of said pattern, for a multilayer stack consisting of four layers are, preferably:

ZnO/Ag/ . . . ZnO/Si₃N₄ (7 to 15/7 to 15/ . . . 7 to 15/23 to 65 nm) and preferably: ZnO/Ag/Ti/ZnO/Si₃N₄
7 to 15/7 to 15/0.2 to 2/7 to 15/23 to 65 nm.

The metal micromesh 4, constituting the front electrode of the carrier substrate, is then covered with an antireflection element which may be of the monolayer type or, preferably, a multilayer stack consisting of interferential layers, which element is based on materials that are transparent in the desired wavelength range, especially in the visible and near-infrared ranges, at least in a wavelength range extending from 400 to 1100 nm. The antireflection coating is present at least at the openings of the micromesh, inside and/or above these openings. In one embodiment, advantageous from the standpoint of ease of fabrication of the carrier substrate, the antireflection coating covers the entire micromesh. The layer or layers of the antireflection element are intended to provide two functions, namely, on the one hand, the function of reducing the reflection at the interface with the layer of the functional element 7 with which it is in contact (especially silicon or germanium or CdTe) and with the substrate 2 and, on the other hand, the function of protecting the glass assembly from the hydrogen plasma during the step of depositing silicon or germanium and protecting it from the moisture of the ambient air.

The multilayer stack consisting of interferential layers is formed from thin layers made of slightly conducting materials, namely semiconductors such as for example lightly doped TCOs, in particular of the oxide or nitride type, the refractive indices of which are alternately high and low. Such a multilayer stack could be of the type described in patent application WO 01/94989.

According to one embodiment of the invention, provision is made for the refractive index of that layer of the interferential multilayer stack 5 which is in contact with the substrate 2 to be as close as possible to the refractive index of said substrate, i.e. in the case of the glass substrate 2, close to n=1.5. Likewise, the refractive index of that layer of the interferential multilayer stack 5 which is in contact with the functional element 7 will have a refractive index as close as possible to that of the layer of said stack with which it is in contact, i.e. the silicon layer in the present example, with index n=4.

The determination of the number, thickness and indices of the intermediate layers falls within the general knowledge of a person skilled in the art, who has at his disposal methods and software for optimizing these various parameters.

Of course, the transparent conducting micromesh, having submillimeter-sized openings, possibly in an arrangement which is aperiodic in at least one direction and random, may be obtained by any process other than that described above.

FIG. 2 shows the transmission spectrum of a carrier substrate according to the invention (curve a) and, for comparison, the transmission spectrum of a carrier substrate of the same type, the electrode of which consists in a known manner of fluorine-doped tin oxide SnO₂:F (curve b). This thus shows, on the one hand, that, in the zone extending from the visible to the near-infrared (λ=380 to 1100 nm), the transmission of the carrier substrate according to the invention is much more uniform and that, in particular in the near-infrared, it is higher than that of the carrier substrate according to the prior art.

It may also be seen, on the other hand, in FIG. 2, in which the absorption spectra of these two carrier substrates have also been respectively shown (curve c: absorption of the carrier substrate according to the invention and curve d: absorption of a carrier substrate of the same type, the electrode of which consists in a known manner of fluorine-doped tin oxide SnO₂:F), that the absorption of the carrier substrate according to the invention is very much lower than that of the reference substrate over the entire extent of the visible spectrum and in the near-infrared.

According to the invention, depending on the desired specific applications, it is possible to employ a monolayer antireflection element or a multilayer stack, as described above.

In a first alternative embodiment of the invention, a carrier substrate is formed in which the antireflection element is of the monolayer type and comprises niobium-doped titanium dioxide TiO₂:Nb with a doping level of 0.5 to 10% so as to make it slightly conducting and to prevent absorption in the near-infrared range. The thickness of this monolayer was determined by calculation to be 60 nm. Thus, a refractive index of 2.4 was obtained for this monolayer. FIG. 4 (curve b) shows the reflection spectrum of such a carrier substrate, on which a silicon layer has been deposited so as to simulate the active layer of a solar cell.

In a second alternative embodiment of the invention, a carrier substrate of the same type is formed, in which the antireflection coating is of the bilayer type and comprises an SiOSn:F first layer, this being a mixed oxide, the refractive index of which may be adjusted in a controlled manner by a simple law of mixtures and the value of which is set at n=1.7, and which was deposited on the glass substrate 2. This layer is fluorine-doped with a doping level of 0.1% so as to make it slightly conducting. The second layer, which is in contact with the silicon layer 7 of the functional elements 6, is again made of niobium-doped titanium oxide TiO₂:Nb, which possesses a refractive index of 2.4 when it is in the anatase form or a refractive index close to n=2.7 when in the rutile form. The respective thicknesses of the first and second layers of this multilayer antireflection stack were determined, in a known manner by calculation, to have respective values of 70 nm and 40 nm. FIG. 4 (curve c) shows the reflection spectrum of a carrier substrate according to the invention provided with such an antireflection bilayer, on which, as previously, a silicon layer was deposited.

In a third alternative embodiment of the invention, a carrier substrate is formed in which the antireflection element consists of a trilayer stack, the outermost layers of which are in contact with the substrate 2 and with the silicon layer 7 respectively and are of the same nature as in the previous example. Placed between these layers is a layer of fluorine-doped tin dioxide SnO₂:F. The thicknesses of these three layers were determined in a known way by calculation and are, for the first to the third layer respectively: 155 nm, 40 nm and 55 nm. As previously, the third layer is covered with a silicon layer. As shown in FIG. 3, the substrate 2 is different from that used previously in that it has itself received an antireflection coating 8. The reflection spectrum of such a carrier substrate is shown as curve a in FIG. 4.

It may be seen in FIG. 4 that the present invention (curves a, b and c) makes it possible to increase the light transmission both in the visible range and the near-infrared range. This increase that can be achieved, in the case of the embodiment represented by curve a, is 10% in the visible range and 15% in the near-infrared range. The light transmission of a substrate with the electrode according to the invention both in the visible range and the near-infrared range (λ=380 to 1100 nm) is greater than 75%, preferably between 85% and 89% (excluding the antireflection multilayer stack).

According to the invention, it will be possible to deposit an overblocker element on the metal of the micromesh so as to protect the latter from oxidation.

In a preferred embodiment of the invention, the layer lying at the interface between the absorber and the antireflection element is lightly doped or even undoped so as to match its work function to the material of the functional layer.

For example, if the lightly doped layer in contact with the Si is an Al-doped ZnO, it is possible to use an intrinsic ZnO layer or a lightly doped ZnO layer with a thickness ranging from a few nm to a few tens of nm. Likewise, if the multilayer stack terminates in a TiO₂:Nb layer, the work-function-matching layer will be an undoped or lightly doped TiO₂ layer with a thickness of a few nm.

According to another embodiment of the invention, the final layer of the antireflection multilayer stack located at the interface with the absorber material will be textured so as to improve the antireflection effect.

The present invention thus proves to be most particularly advantageous for use in all applications in which it is important to have a carrier substrate capable of optimizing the transmission and of reducing the absorption in the visible and near-infrared ranges and the electrode of which has an intrinsic conductivity sufficient to free an antireflection layer, placed thereon, of any constraint as regards the conductivity. According to the invention, the antireflection coating is semiconducting and in contact both with the conducting micromesh and with the absorber element of the solar cell, into the front face of which the carrier substrate is integrated. Thus, the antireflection coating, which is semiconducting, is capable of collecting the charges from the absorber element in the direction of the conducting micromesh. In particular, according to the invention, it is at least one layer of the antireflection coating, in contact with the micromesh and intended to be in contact with the functional element of a solar cell equipped with the carrier substrate, which is semiconducting, it being possible for the carrier substrate to include other layers between the substrate having a glass function and the semiconducting layer of the antireflection coating. This or these other layers may be placed beneath the micromesh or housed in the openings of the micromesh, and are also preferably semiconducting.

1. A carrier substrate, comprising a substrate especially having a glass function, transparent at least in the visible and near-infrared ranges and receiving a conducting electrode which is transparent at least in the visible and near-infrared ranges, the electrode carrier substrate being intended to constitute, in combination with functional elements, a solar cell, wherein,
the electrode comprises a micromesh made of conducting material having submillimeter-sized openings; and
the micromesh is in contact with an at least slightly conducting antireflection coating facing that one of the functional elements with which it is intended to be in contact.

2. The carrier substrate as claimed in claim 1, wherein the micromesh is based on a metal or a metal alloy, especially silver or gold.

3. The carrier substrate as claimed in claim 1, wherein the micromesh comprises a thin-film multilayer stack comprising at least a metallic first layer and two dielectric-based coatings located one below and the other above the metallic first layer, and a protective metallic layer placed immediately above and in contact with the metallic first layer.

4. The carrier substrate as claimed in claim 1, wherein the distribution of said submillimeter-sized openings is aperiodic in at least one direction.

5. The carrier substrate as claimed claim 1, wherein the distribution of said submillimeter-sized openings is random.

6. The carrier substrate as claimed in claim 1, wherein the antireflection coating consists of a multilayer stack comprising at least two thin layers made of a dielectric material, the refractive indices of the layers of which, in contact with the substrate and intended to be in contact with the functional element respectively, have refractive indices close to the refractive indices of said substrate and said element.

7. The carrier substrate as claimed in claim 6, wherein the multilayer stack of the antireflection coating consists of at least three thin layers, the refractive indices of which are alternately high and low.

8. The carrier substrate as claimed in claim 7, wherein the layer of the antireflection multilayer stack that is in contact with the substrate is based on mixed oxides, nitrides or oxynitrides based on Si, Sn or Zn, used alone or as a mixture, and optionally doped (with F, Al or Sb) and the layer in contact with the functional multilayer stack is based on at least one transparent conductive oxide chosen especially from TiO₂, ZnO, SnO₂, SnZnO, ITO, IZGO and IZO and optionally doped (with Nb, Ta, Al, Sb or F).

9. The carrier substrate as claimed in claim 8, wherein the first layers in contact with the substrate function as barriers for stopping alkaline metals from said substrate.

10. The carrier substrate as claimed in claim 1, wherein the substrate includes, on its external face, an antireflection layer.

11. The carrier substrate as claimed in claim 1, wherein the resistivity of the layers of the antireflection coating is between 0.1 and 50 milliohms.cm.

12. The carrier substrate as claimed in claim 1, wherein the metal micromesh is covered with an overblocker element.

13. The carrier substrate as claimed in claim 1, wherein the layer of the antireflection element, which is intended to be at the interface between the functional element and the antireflection element, is lightly doped or even undoped so as to match its work function to the material of the functional element.

14. The carrier substrate as claimed in claim 13, wherein said layer consists of a highly doped transparent conductive oxide (TCO) preferably with a thickness of between 5 and 10 nanometers.

15. A solar cell incorporating a carrier substrate as claimed in claim 1.

16. A method comprising providing a carrier substrate as claimed in claim 1 for constituting a solar cell.

17. A process for fabricating a carrier substrate as claimed in claim 1, comprising:
depositing a mask layer on the substrate using a solution of stabilized colloidal particles dispersed in a solvent;
drying the mask layer until a two-dimensional network of interstices is obtained;
depositing a conducting, especially metallic, micromesh material in the interstices until at least a fraction of the depth of the interstices has been filled; and
depositing the slightly conducting antireflection coating facing that one of the functional elements with which it is intended to be in contact.

18. The process as claimed in claim 17, wherein the substrate on which the mask layer is deposited is provided, on its external face, with an antireflection coating.

19. A solar cell comprising a carrier substrate as claimed in claim 1.
